(19) United States
(12) Patent Application Publication
(10) Pub. No.: US 2005/0169167 A1
(43) Pub. Date: Aug. 4, 2005

(54) Line format setting method and communication apparatus using the line format setting method

(76) Inventor: Hideaki Tazawa, Kawasaki (JP)

Correspondence Address: KATTEN MUCHIN ROSENMAN LLP, 575 MADISON AVENUE, NEW YORK, NY, 10022-2585, US

(21) Appl. No.: 11/062,065

(22) Filed: Feb. 18, 2005

Related U.S. Application Data
(63) Continuation of application No. PCT/JP02/12534, filed on Nov. 29, 2002.

(51) Int. Cl. G06F 11/00; G01R 31/08

(52) U.S. Cl. 370/216; 370/242

(57) ABSTRACT

A line format setting method is disclosed. The line format setting method includes the steps of detecting a line alarm of each line in a plurality of lines, inserting path alarm information into all paths inside a line from which the line alarm is detected, detecting the path alarm information in all paths inside the plurality of lines, detecting concatenation information of each of the plurality of lines, selecting a reception line for receiving the concatenation information in accordance with the path alarm information in all paths inside the plurality of lines, and setting a line format of an STS bundle line by using the concatenation information of the selected reception line.

### CROSS-REFERENCE TO RELATED APPLICATIONS

This application is a U.S. continuation application filed under 35 USC 111(a) claiming benefit under 35 USC 120 and 365(c) of PCT application JP 2002/012534, filed Nov. 29, 2002. The foregoing application is hereby incorporated herein by reference.

### BACKGROUND OF THE INVENTION

1. Field of the Invention

The present invention relates to a line format setting method and a communication apparatus using the line format setting method, and more particularly to a line format setting method in a ring network and a communication apparatus using the line setting method.

2. Description of the Related Art

In recent years and continuing, the number of entities entering the communication service business is growing and the needs expected for communication services are becoming diverse. Accordingly, in many cases, entities owning communication lines are providing communication lines to those who do not own such communication lines. In such cases, there is a growing demand for STS bundle lines which are lines that enable automatic recognition of a line format of a main signal without any intervention and automatic setting of the line format once the entity owning a communication line(s) designates the communication line(s) to be provided.

Furthermore, a ring network configuration, for example, UPSR (Unidirectional Path Switched Ring) is currently employed as a main stream configuration for network protection. Accordingly demands for applying the STS bundle lines to the UPSR network are growing.

Functions of the bundle lines are described below using OC-48 (Optical Carrier-48) communication lines in a SONET (Synchronous Optical Network). In a case of using the OC-48 lines, the STS can be set with one line of STS-48c, four lines of STS-12c, eighteen lines of STS-3c, or a combination of STS-12c and STS-3c.

The STS bundle line does not allow bidirectional transmission of different format settings. That is, in a case where transmission from line S1-1 to line S2-1 is set with an STS-1 format, transmission from line S2-1 to line S1-1 is only allowed to be set with the STS-1 format, and cannot be set with a STS-3 format. Accordingly, it is required to prioritized concatenation information from either one of the lines and set a format thereto.

Here, concatenation information refers to information regarding the line format. For example, in a case of the OC-48 lines, STS-1, STS-3c, STS-12c, and STS-48c are included as formats. Accordingly, the STS bundle line has prioritized setting information (configuration setting information) regarding concatenation information for a reception line, thereby allowing prioritized format setting in accordance with the concatenation information from the prioritized line.

FIG. 1 is a drawing showing an exemplary configuration of a communication apparatus 10 including a conventional STS bundle function, and FIG. 2 is a drawing showing a configuration of a software process function in a CPU 14 shown in FIG. 1. In FIG. 1, concatenation detection parts 12A, 12B in the communication apparatus 10 detect concatenation information from pointers in an SOH (Section OverHead) of input signals from lines S1-1 and S2-1, and report detection results to a CPU 14.

Line alarm detection parts 16A, 16B detect line alarms including, for example, LOS (Loss Of Signal), LOF (Loss Of Frame) and AIS-L, and report detection results to the CPU 14. Cross connection parts 18A and 18B respectively execute a format setting when receiving a format setting execution command from the CPU 14.

In the software process in the CPU 14, a concatenation information reception line determination part 20 compares the alarm state for each of lines S1-1 and S2-1. A selector 22, in accordance with the comparison, selects concatenation information of the line having higher line quality. When there is no line alarm from either lines or when there are line alarms from both lines, concatenation information of the prioritized line, (configuration set) line (e.g. S1-1) is selected.

A format setting execution part 24 sends a format setting execution command to the cross-connection parts 18A and 18B shown in FIG. 1 based on the selected concatenation information.

However, the conventional communication apparatus, which selects concatenation information for the reception line by comparing the line alarm state, faces the problems described below in a case where the STS bundle lines are applied to the UPSR network.

FIG. 3 shows a conventional exemplary configuration of the UPSR network applied with the STS bundle line. In FIG. 3, the lines that are illustrated with underlined numerals indicate configuration set lines. Here, bundle line setting of line S3-1 is executed between the lines S1-1 and S2-1 at the nodes which execute path switching, as nodes A and C.

In this case, lines S1-1 and S2-1 of the UPSR network are set as configuration settings, it is necessary to prioritize the lines S1-1 and S2-1, and the default of the path switch is prioritized.

Here, in a case where a signal input from line S3-1 of node A changes from STS-1 to STS-3c, the format can be properly changed for all nodes when there is no fault in the network.

However, in a case where there is a fault in the line between nodes A and B (see \mathring{1} in FIG. 3), the following operation is executed.

Formats are properly changed in nodes A and D. In node B, the concatenation information for the reception line is switched to line S2-1 since a line alarm is generated in line S1-1 (see \mathring{2} in FIG. 3). Accordingly, format cannot be changed until the format of node C is changed. In node C, although an AIS-P (Alarm Indication Signal Path) is generated in all of the paths of line S1-1 (see \mathring{3} in FIG. 3), no line alarm is generated. Therefore, the reception line of concatenation information remains as S1-1, and the format cannot be changed to S2-1 (see \mathring{4} of FIG. 3). Hence, format change cannot be achieved in nodes B and C, thereby causing a mismatch of format in the network, and discconection of the main signal.

In a case where a LOP-P (Loss Of Pointer Path) is generated in the path in the STS bundle line, proper concatenation information cannot be detected. This causes problems such as inability to execute format setting or execution of an incorrect format setting.

### SUMMARY OF THE INVENTION

It is an object of the present invention to provide a line format setting method and a communication apparatus using the line format setting method enabling automatic setting of a format to be reliably executed in a case where a fault occurs in a UPSR network and also enabling recovery of a fault when using an STS bundle line in a UPSR network.

In order to achieve the object, the present invention provides a line format setting method including the steps of detecting a line alarm of each line in a plurality of lines, inserting path alarm information into all paths inside a line from which the line alarm is detected, detecting the path alarm information in all paths inside the plurality of lines, detecting concatenation information of each of the plurality of lines, selecting a reception line for receiving the concatenation information in accordance with the path alarm information in all paths inside the plurality of lines, and setting a line format of an STS bundle line by using the concatenation information of the selected reception line.

### BRIEF DESCRIPTION OF THE DRAWINGS

Further objects, features and advantages of the present invention will become more apparent from the detailed description and the accompanying drawings.

FIG. 1 is a drawing showing an exemplary configuration of a communication apparatus 10 including a conventional STS bundle function;

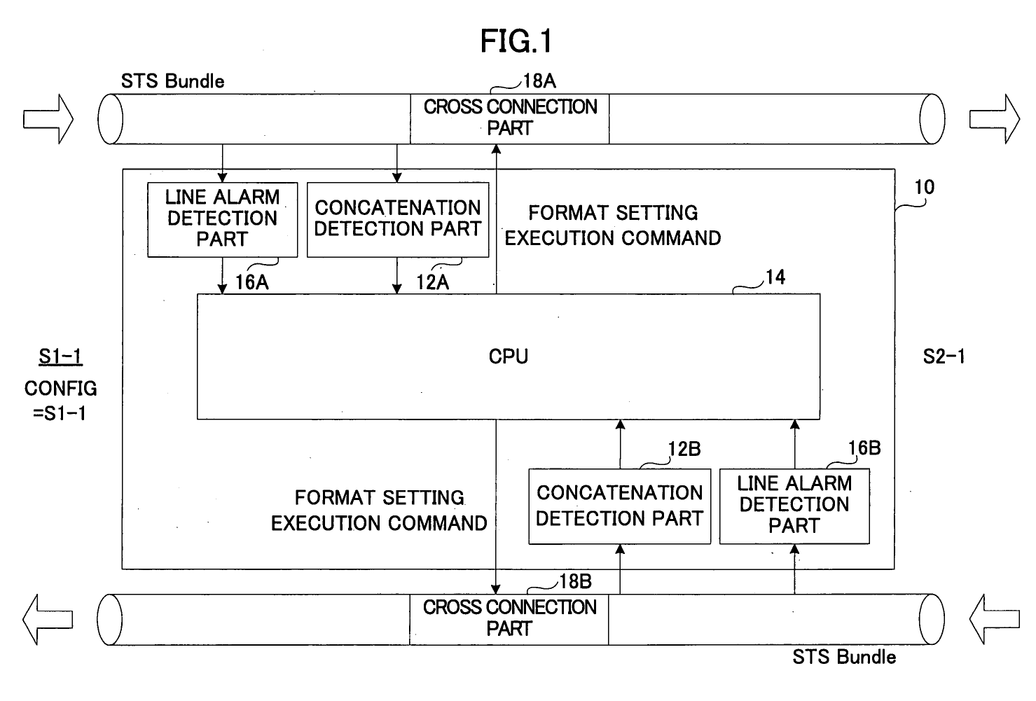

FIG. 2 is a drawing showing a configuration of a software process function in a CPU 14 shown in FIG. 1;

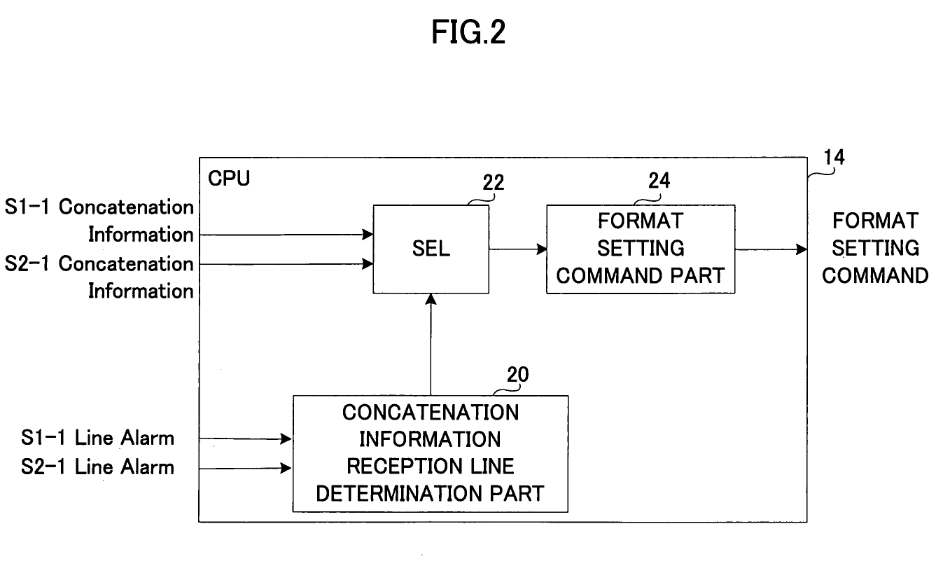

FIG. 3 is a drawing showing a conventional exemplary configuration of the UPSR network applied with the STS bundle line;

FIG. 4 is a drawing showing a configuration of a communication apparatus including an STS bundle function according to a first embodiment of the present invention;

FIG. 5 is a drawing showing a configuration of a software process function in a CPU 34 shown in FIG. 4;

FIG. 6 is a drawing showing a configuration of a communication apparatus including an STS bundle function according to a second embodiment of the present invention;

FIG. 7 is a drawing showing a configuration of a software process function in a CPU 34 shown in FIG. 6;

FIG. 8 is a drawing showing a configuration of an apparatus having fixed slots used for the UPSR network according to a third embodiment of the present invention;

FIG. 9 is a drawing showing a configuration of an apparatus having slots where the slots to be used for the UPSR are not specified according to a fourth embodiment of the present invention;

FIG. 10 is a drawing showing an exemplary configuration of a circuit part for recognizing ring opponent line information;

FIG. 11 is a timing chart for describing automatic detection of ring opponent channel information;

FIG. 12 is a drawing showing a configuration of a communication apparatus having an STS bundle function according to a fifth embodiment of the present invention;

FIG. 13 is a drawing showing a configuration of a software process function in a CPU 100 shown in FIG. 12;

FIG. 14 is a drawing showing an exemplary configuration of a UPSR network using the communication apparatus of the fifth embodiment of the present invention as a node;

FIG. 15 is a drawing showing a configuration of a communication apparatus having an STS function according to a sixth embodiment of the present invention;

FIG. 16 is a drawing showing a configuration of a software process function in a CPU 110 shown in FIG. 15; and

FIG. 17 is a drawing showing an exemplary configuration of a UPSR network using the communication apparatus of the sixth embodiment of the present invention as a node.

### DESCRIPTION OF THE PREFERRED EMBODIMENTS

Embodiments of the present invention are described below with reference to the drawings.

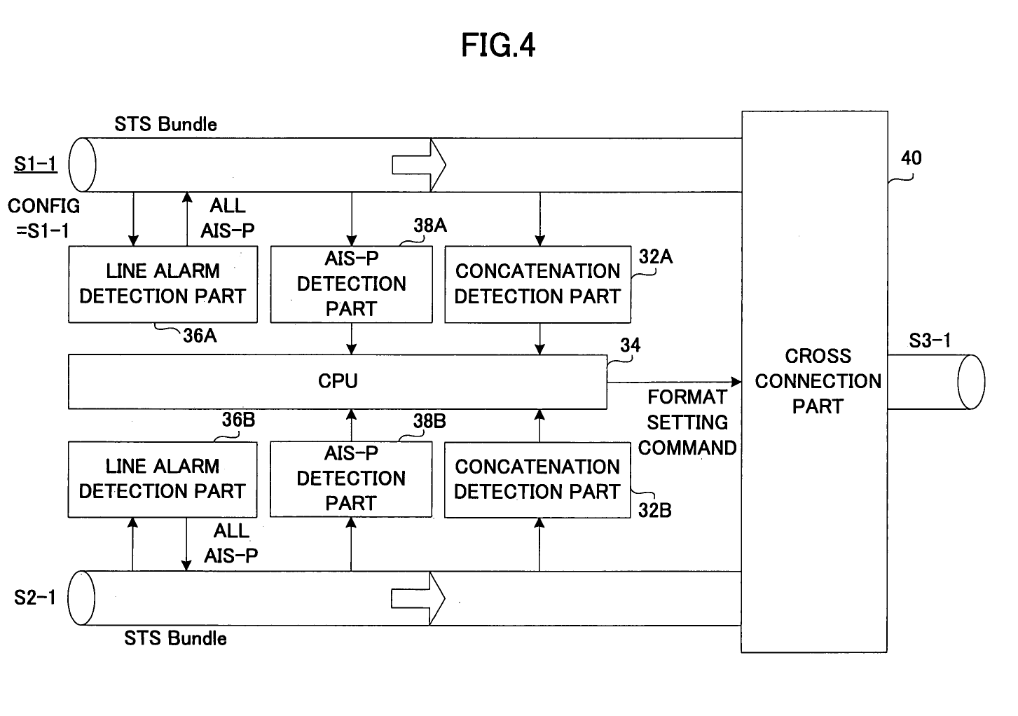

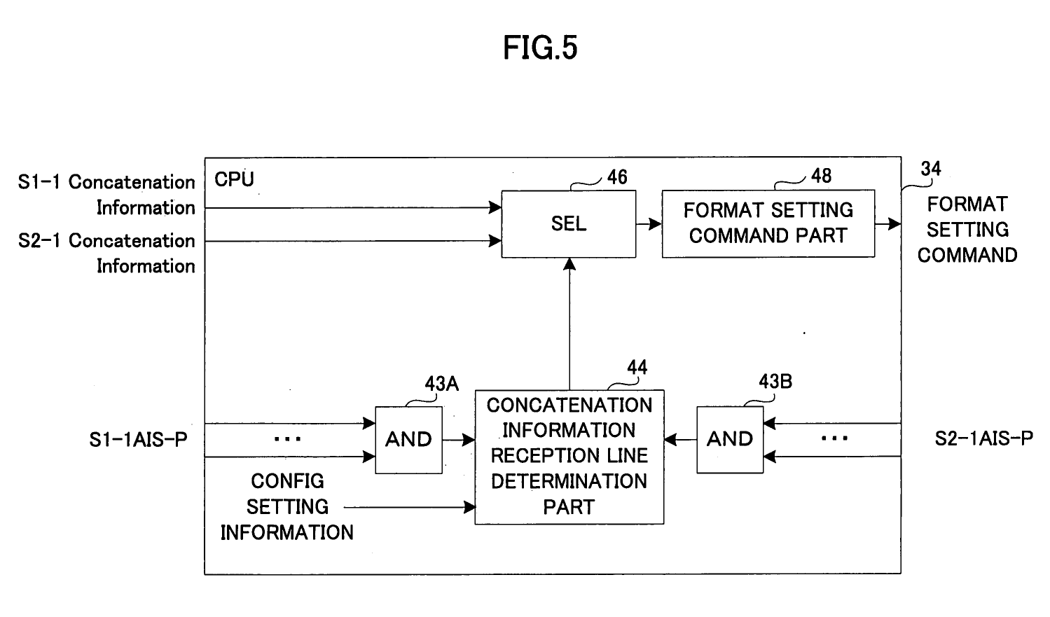

FIG. 4 is a drawing showing a configuration of a communication apparatus including an STS bundle function according to a first embodiment of the present invention, and FIG. 5 is a drawing showing a configuration of a software process function in a CPU 34 shown in FIG. 4.

In FIG. 4, concatenation detection parts 32A, 32B detect concatenation information from H1, H2 which are pointers in the SOH of the input signals of lines S1-1 and S2-1, and report detection results to the CPU 34.

Line alarm detection parts 36A, 36B detect each line alarm including LOS, LOF, and AIS-L and insert AIS-P (Alarm Indication Signal Path) into all paths in the lines when a line alarm is detected.

AIS-P detection parts 38A, 38B detect AIS-P of each line, and report detection results to the CPU 34. A cross-connection part 40 executes line format setting when receiving a format setting execution command from the CPU 34.

In FIG. 5, a concatenation information reception line determination part 44 determines the line for receiving concatenation information by using the AIS-P in the STS bundle of both lines S1-1 and S2-1, and executes switching of a selector 46.

The AIS-P of all paths in the STS bundle of line S1-1, being subject to logical multiplication in an AND circuit 43A, and the AIS-P of all paths in the STS bundle of line S2-1, being subject to logical multiplication in an AND circuit 43B, are sent to the concatenation information reception line determination part 44. The concatenation information reception line determination part 44 switches the reception line of concatenation information when AIS-P is generated in all paths in the STS bundle. The switching is, however, not executed in a case where there is one or more paths in the paths of the STS bundle that include no AIS-P. In a case where all paths in both lines are AIS-P, or in a case where no path in either line is AIS-P, priority is given to the concatenation information of the configuration set line.

A format setting command part 48 reports a format setting command to the cross-connection part 40 in accordance with the concatenation information selected in the selector 46.

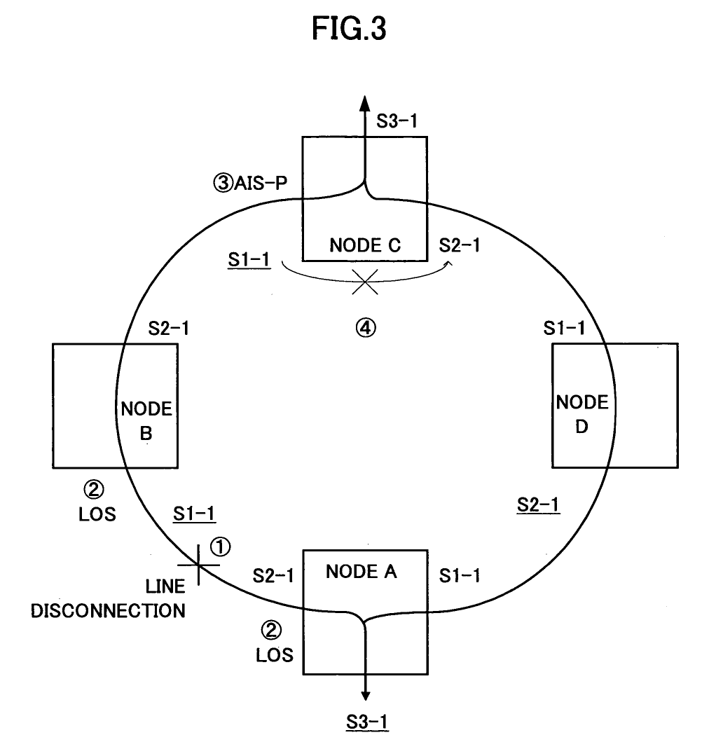

With the first embodiment of the present invention, the reception line for concatenation information is selected by using the AIS-P information of all paths in the STS bundle. Accordingly, even in a case where the reception line for concatenation information cannot be selected by comparing line alarms when a fault occurs between nodes A and B as shown in the conventional example of FIG. 3, the node C can switch the reception line for concatenation information to line S2-1 since all paths in the STS bundle of S1-1 become AIS-p. Accordingly, automatic setting of line format can be precisely achieved even when a fault occurs in the UPSR network.

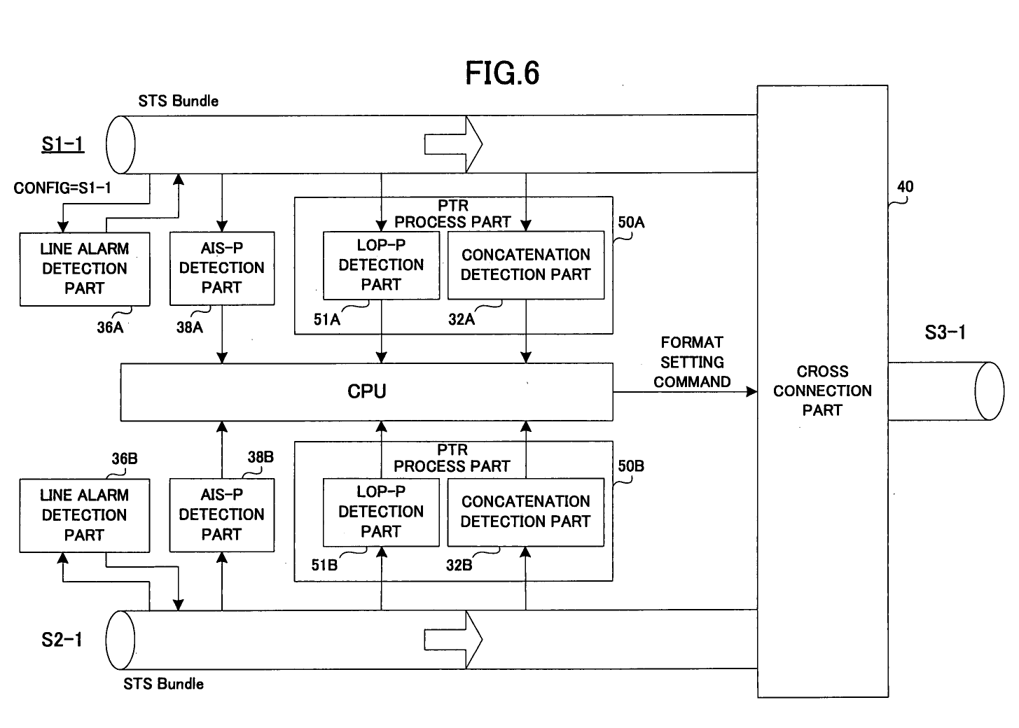

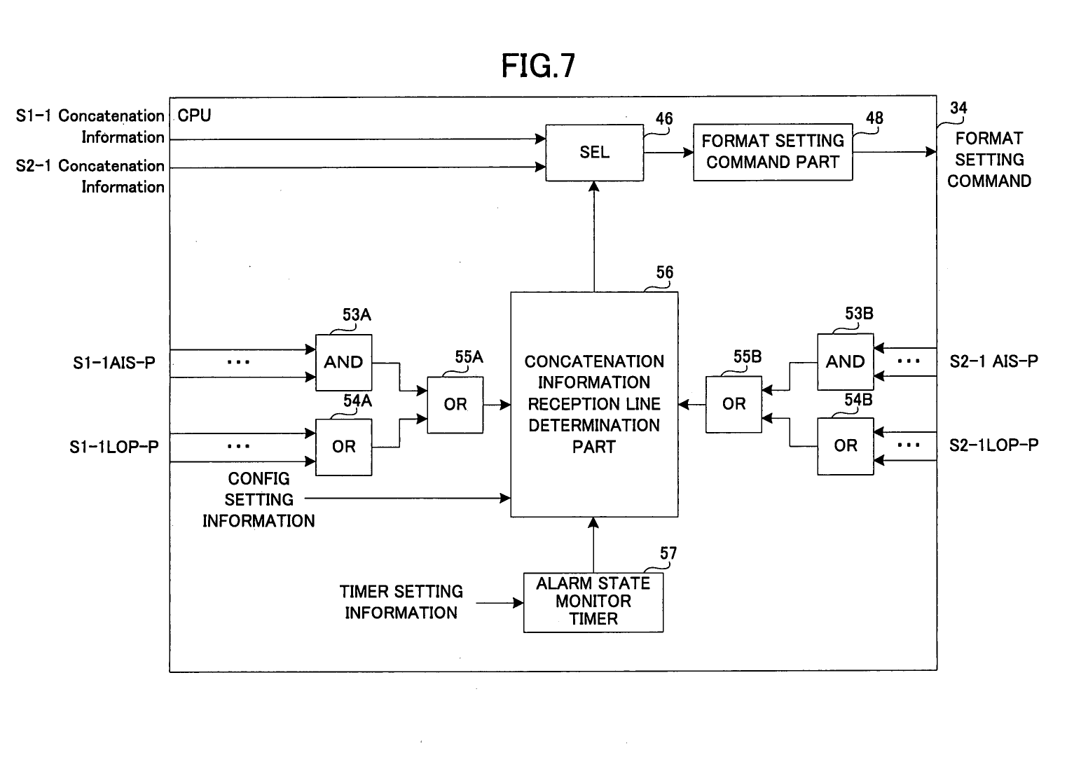

FIG. 6 is a drawing showing a configuration of a communication apparatus including an STS bundle function according to a second embodiment of the present invention, and FIG. 7 is a drawing showing a configuration of a software process function in a CPU 34 shown in FIG. 6. In FIGS. 6 and 7, like components are denoted with like numerals as of FIGS. 4 and 5.

In FIG. 6, line alarm detection parts 36A, 36B detect line alarms including LOS, LOF, and AIS-L of lines S1-1 and S2-1, and insert AIS-P into all paths of the line whenever a line alarm is detected. AIS-P detection parts 38A, 38B detect AIS-P, and report the detection results to the CPU 34.

In PTR process parts 50A, 50B and concatenation detection parts 32A, 32B detect concatenation information from H1, H2 bytes which are pointers in the SOH in the input signals in lines S1-1 and S2-1, respectively, and LOP-P detection parts 51A, 51B detect LOP-P information of the H1, H2 bytes. The detection results are respectively reported to the CPU 34. The cross-connection part 40 executes line format setting when receiving a format setting execution command from the CPU 34.

In FIG. 7, logical multiplication of the AIS-P information of all paths in the STS bundle of lines S1-1, S2-1 are respectively obtained in AND circuits 53A and 53B, and logical addition of the LOP-P in each STS bundle are obtained in OR circuits 54A and 54B. Then, logical addition of the aforementioned logical multiplication and logical addition are obtained in OR circuits 55A and 55B, to thereby be sent to the concatenation information reception line determination part 56. The concatenation information reception line determination part 56 determines the reception line for the concatenation information according to the sent information and switches the selector 46.

In a case where an LOP-P alarm is generated in any one of the STS bundles or in a case where an AIS-P alarm is generated in all paths, concatenation information is selected from the line having no alarm.

An alarm state monitor timer 57, serving to monitor the alarm state, starts a timer when an alarm is generated and re-starts (resets) the timer when an alarm is cleared within a predetermined timer period. In a case where the alarm is not cleared within the timer period, the selector is switched in accordance with the determination results of the concatenation information reception line determination part 56. The monitoring time can be changed by setting of the timer period.

The format setting command part 48, in accordance with the concatenation information selected by the selector 46, reports the format setting command to the cross-connection part 40.

With the second embodiment of the present invention, incomplete format setting due to generation of LOP-P can be prevented by determining the reception line for concatenation information by using LOP-P information in the STS bundle.

Furthermore, by monitoring the determination results regarding the reception line for the concatenation information with the alarm state monitor timer 57, the switching of the reception line for the concatenation information can only be achieved by the LOP-P (except for the LOP-P generated when changing the line format setting) generated when a fault occurs. Accordingly, automatic setting of line format can be precisely achieved.

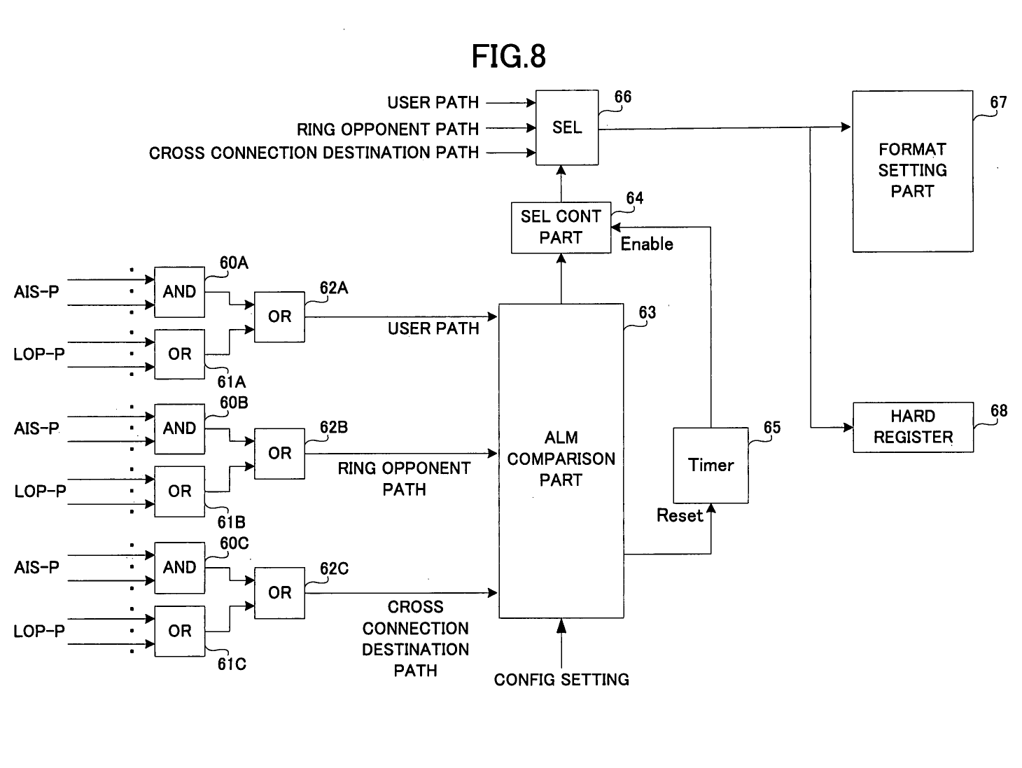

The above-described determination of the reception line of the concatenation information and the setting of the line format may also be executed with hardware. FIG. 8 is a drawing showing a configuration of an apparatus having fixed slots used for the UPSR network according to a third embodiment of the present invention. It is to be noted that add-drop is executed in this configuration.

In FIG. 8, logic multiplication of AIS-P information with respect to all paths in the STS bundle in a user path (e.g. line S1-1), a ring opponent path (e.g. line S2-1), and a cross-connection destination path (e.g. line S3-1), respectively, are obtained in AND circuits 60A-60C, logic addition of LOP-P in each STS bundle is obtained in OR circuits 61A-61C, and logic addition of the foregoing logic multiplication and the logic addition are obtained in OR circuits 62A-62C and are supplied as alarm information to an ALM comparison part 63.

The alarm comparison part 63 determines the reception line for the concatenation information according to the alarm information of each path in the user line, the ring opponent line, and the cross-connection destination line, and reports the determination result to a selector control part 64. Here, in a case where an LOP-P alarm is generated in any one of the STS bundles or in a case where an AIS-P alarm is generated in all paths, concatenation information is selected from the line having no alarm.

A timer part 65 starts a timer when an alarm is generated and stops the timer when the alarm is cleared within a predetermined timer period. When the alarm is continued throughout the timer period, the output of the selector control part 64 is activated. Accordingly, the selector control part 64 executes switching of a selector 66 serving to select the reception line of the concatenation information for each path.

A format setting part 67 sets the line format in a cross-connection part (not shown) in accordance with the concatenation information for each path selected by the selector 66. Furthermore, the selected concatenation information for each path is stored in a hard register 68. Software can receive the information in the hard register 68 and recognize the format change executed by hardware.

With the third embodiment of the present invention, by providing a configuration of determining and switching the reception line for concatenation information with use of hardware which includes an apparatus with fixed slots being applicable to a UPSR network, quick recovery can be achieved in a case where a fault occurs during switching of line format in the UPSR network.

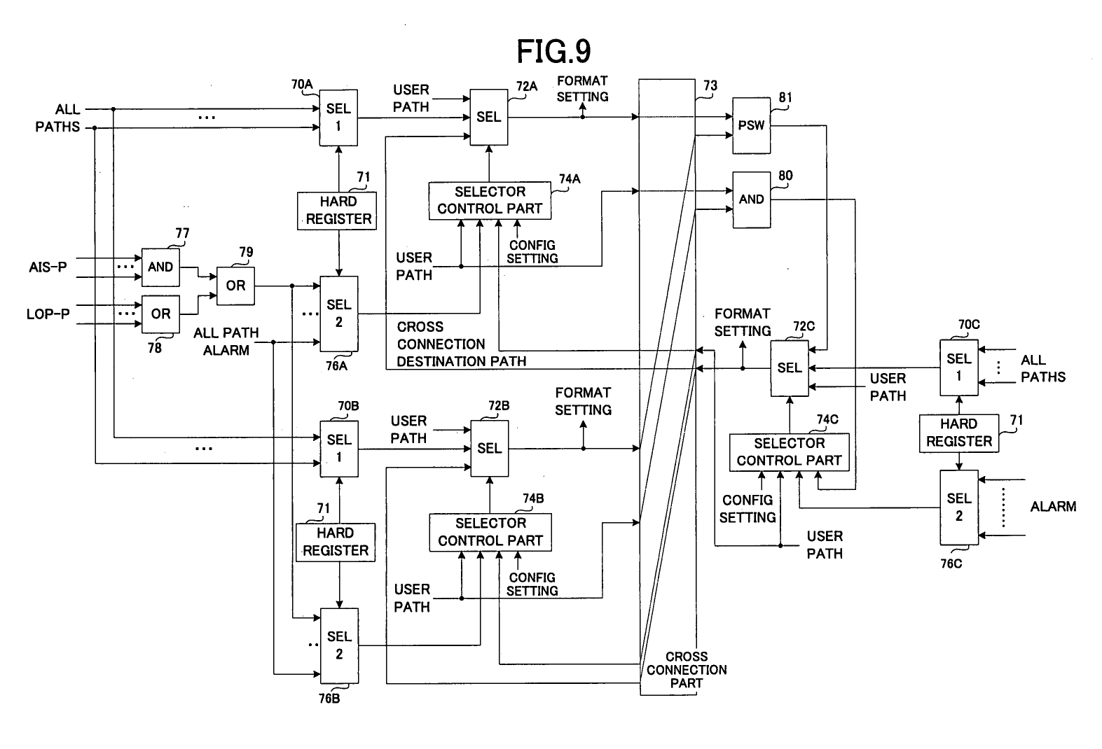

FIG. 9 is a drawing showing a configuration of an apparatus having slots where the slots to be used for the UPSR are not specified according to a fourth embodiment of the present invention.

In a case where the slots to be used for the USPR network are not designated, the ring opponent line in the UPSR network is to be set to a hard register 71. Each of selectors 70A, 70B, and 70C (SEL 1) selects concatenation information of the ring opponent line from the concatenation information of all lines based on the ring opponent line information set to the hard register 71.

Each of selectors 72A, 72B, and 72C selects path alarm information in the ring opponent line from the alarm information of all paths based on ring opponent line information set to the hard register 71. It is to be noted that alarm information of each path is acquired by obtaining the logical multiplication of all paths in each bundle in an AND circuit 77, obtaining the logical addition of LOP-P of all paths in each bundle in an OR circuit 78, and obtaining the logical addition of the foregoing logical multiplication and the foregoing logical addition in an OR circuit 79.

Selector control parts 74A, 74B, and 74C determine the reception line of the concatenation information and execute switching in selectors 72A, 72B, and 72C in accordance with the alarm information of the user path, the path alarm information in the ring opponent line selected by selectors 76A, 76B, and 76C, the alarm information of the cross-connection destination, and the configuration setting information.

Then, based on the concatenation information selected by the selectors 72A, 72B, and 72C, format setting of the user path is executed and reported to the hard register 71.

Since there is no ring opponent line in a case of a configuration of an apparatus for a line of a UPSR drop side, each of the selectors 76A, 76B, and 76C has a high level output (include an alarm). Accordingly, selector control parts 74A, 74B, and 74C determine the reception line of the concatenation information in accordance with the alarm information of the user path, the alarm information of the cross-connection destination, and the configuration setting information, and switch the selectors 72A, 72B, and 72C according to the determination results.

It is to be noted that, since there are two cross-connection destination paths in the paths of the drop side, the logical multiplication of the alarm information of the two paths is obtained in the AND circuit 80 and is used as the alarm information of the cross-connection destination path.

In this case, the selector 72C of the drop side makes a selection from either the concatenation information of the user path or the concatenation information of the two paths of the cross-connection destination switched by the path switch (PSW) 81.

In the fourth embodiment of the present invention, determining and switching the reception line of the concatenation information are achieved by using the path alarm information of the ring opponent line set to the hard register 71, the path alarm information of the cross-connection line, and the configuration setting information. Accordingly, even in a case where slots to be used for UPSR are not specified, determination and switching of the reception line of the concatenation information can be achieved with hardware. Thus, quick recovery can be achieved in a case where a fault occurs during switching of line format in the UPSR network.

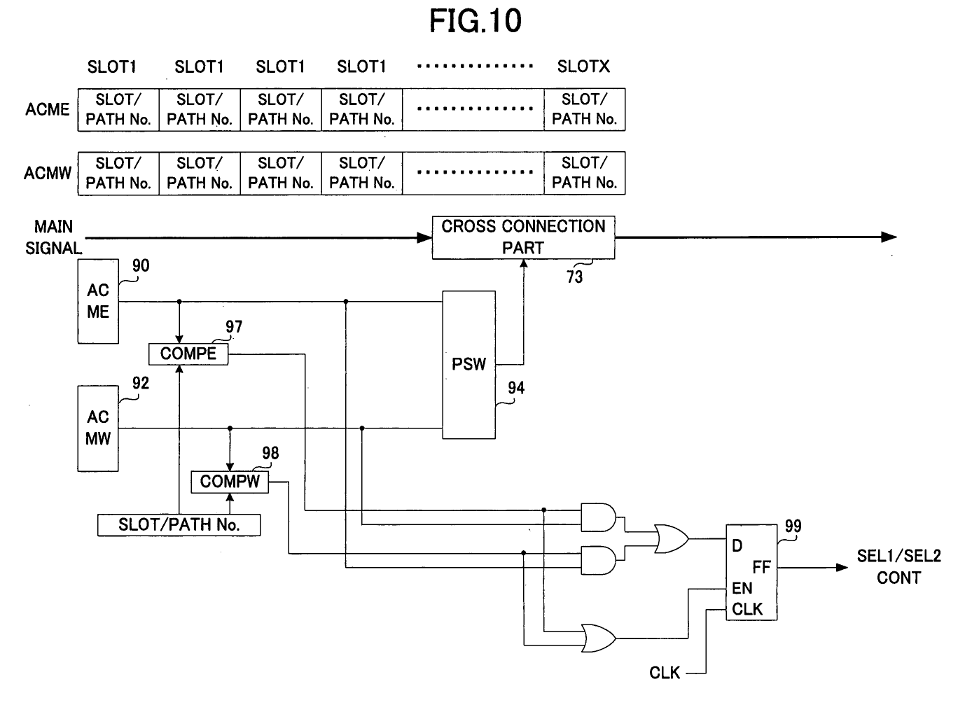

FIG. 10 is a drawing showing an exemplary configuration of a circuit part for recognizing ring opponent line information. In FIG. 10, ACME 90 and ACMW 92 are memories which store information regarding slots that are cross-connected to each path and path number information. The ACME 90 corresponds to an east side of the UPSR, and the ACMW 92 corresponds to a west side of the UPSR. The ACM information for the paths of both the east side and west side are simultaneously transferred as serial data to a path switch (PSW) 94. The path switch 94 selects either one of the information, and the cross-connection part 73 executes line setting based on the selected information (same as the cross-connection part 73 shown in FIG. 9). This is a configuration included in a UPSR compliant cross-connection apparatus.

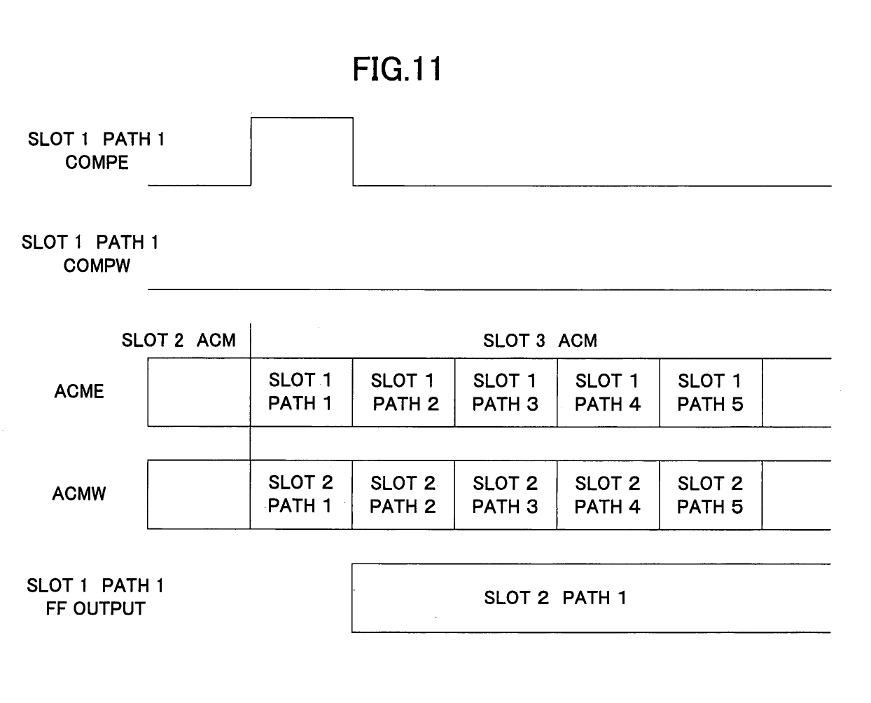

With the present invention, the ACM information can be used for enabling hardware to automatically detect the ring opponent line information. The timing chart in FIG. 11 illustrates an example of detecting a ring opponent destination of slot 1/path 1 in a case of east slot 1, west slot 2, and drop slot 3.

A comparison part (COMPE) 97 and a comparison part (COMPW) 98 compare their own slot and their path number (slot 1, path 1) with information in the ACME 90 and the ACMW 92, and generate a trigger pulse when there is a match. The logical addition of the logical multiplication between the ACME information and the output of the comparison part 98 and the logic multiplication between the ACMW and the output of the comparison part 97 is input to a flip-flop 99 as a hard register, and are latched at the above-described trigger pulse. The stored information in the flip-flop 99 is sent to the selectors 70A-70C (SEL 1) and selectors 76A-76C (SEL 2), for example, shown in FIG. 9.

Since the slot 1/path 1 is set to slot 3/path 1 of the ACME 90, slot 2/path 1 set to the ACMW 92 is output as the ring opponent line information.

This embodiment of the present invention enables hardware to detect ring opponent line information, which is preset to the hard register 71, from ACM information. Accordingly, ring opponent line information of all the paths are not required to be set to the hard register 71, thereby enabling size reduction of the hard register.

Furthermore, the STS bundle function can be achieved with hardware merely by initially setting a conventional cross-connection. Thus, quick recovery can be achieved in a case where a fault occurs during switching of line format in the UPSR network.

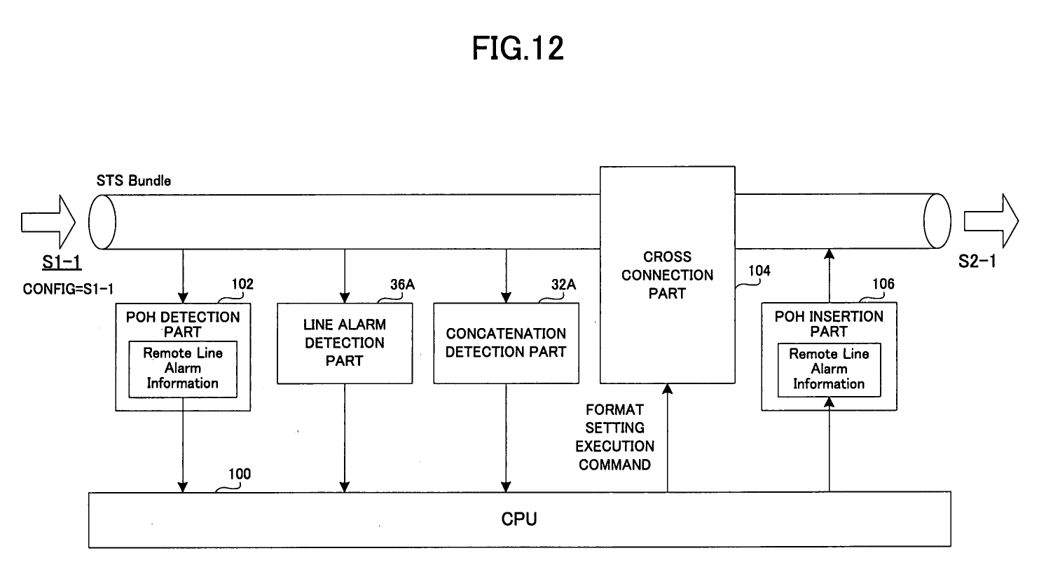

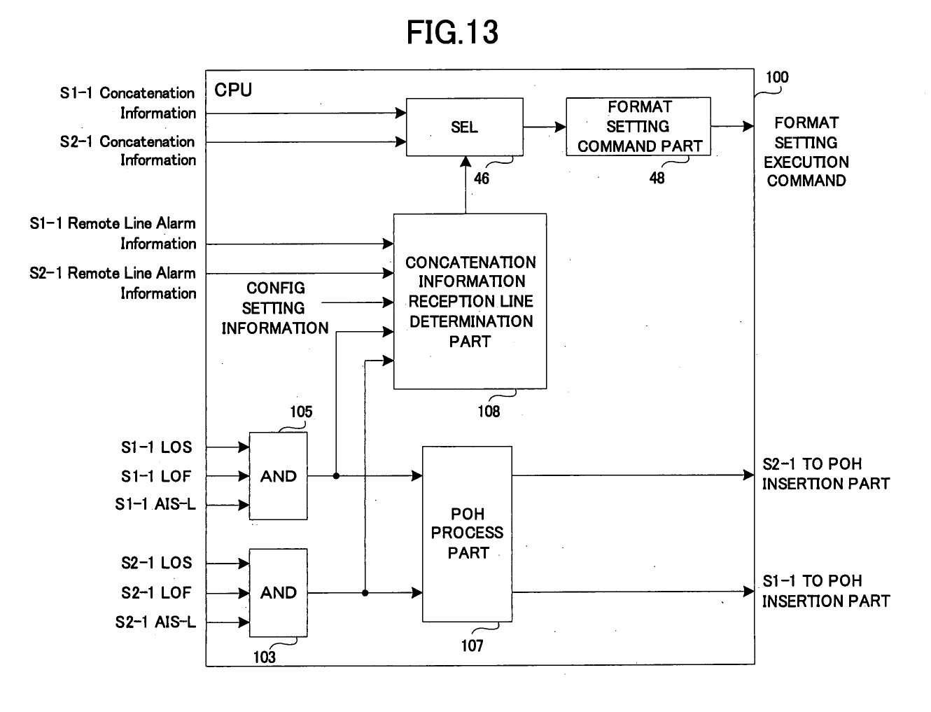

FIG. 12 is a drawing showing a configuration of a communication apparatus having an STS bundle function according to a fifth embodiment of the present invention, and FIG. 13 is a drawing showing a configuration of a software process function in a CPU 100 shown in FIG. 12. In FIG. 12 and FIG. 13, like components are denoted with like numerals as of FIGS. 6 and 7.

In FIG. 12, the concatenation detection part 32A detects concatenation information from H1, H2 bytes which are pointers in the SOH in the input signals in line S1-1, and reports the detection results to the CPU 100. The line alarm detection part 36A detects line alarms including LOS, LOF, and AIS-L of line S1-1 and reports the detection results to the CPU 100.

A POH detection part 102 extracts remote line alarm information from, for example, G1 byte, of a POH (Path Over-Head) of an input signal of the line S1-1, and reports the extracted information to the CPU 100. Here, the POH does not terminate but instead remains to be sent to the next node. A cross-connection part 104 executes a line format setting when receiving a format setting execution command from the CPU 100.

A POH insertion part 106 inserts remote line alarm information into the G1 byte of the POH in the output signal of line S2-1. The same configuration is also provided in the other direction from the line S2-1 to the line S1-1.

In FIG. 13, an AND circuit 105 obtains the logical multiplication of each of the line alarms LOS, LOF, and AIS-L in the line S1-1 and sends the obtained logical multiplication to a POH process part 107. Furthermore, an AND circuit 103 obtains the logical multiplication of each of the line alarms LOS, LOF, and AIS-L in the line S2-1 and sends the obtained logical multiplication to the POH process part 107.

When the logical multiplication from the AND circuit 105 is a high level, the POH process part 107 generates remote line alarm information and reports the generated information to a S2-1 POH insertion part 106 of a path of a cross-connection destination. When the logical multiplication from the AND circuit 103 is a high level, the POH process part 107 generates remote line alarm information and reports the generated information to a S1-1 POH insertion part 106 of a path of a cross-connection destination.

Furthermore, the concatenation information reception line determination part 108 determines the reception line of the concatenation information and switches the selector 46 in accordance with, for example, the remote line alarm information of both lines S1-1 and S2-1 sent from the POH detection part 102, the obtained logical multiplications sent from the AND circuits 105 and 103, and configuration setting information.

Here, in a case where the remote line alarm or the line alarm is generated in either one of the lines, concatenation information is received from the line where no alarm is generated. In a case where the remote line alarm or the line alarm is generated in both lines or in a case where no alarm is generated in both lines, priority is given to the concatenation information of the configuration set line.

The format setting command part 48 reports the format setting command to, for example, the cross-connection part 104 in accordance with the concatenation information selected by the selector 46.

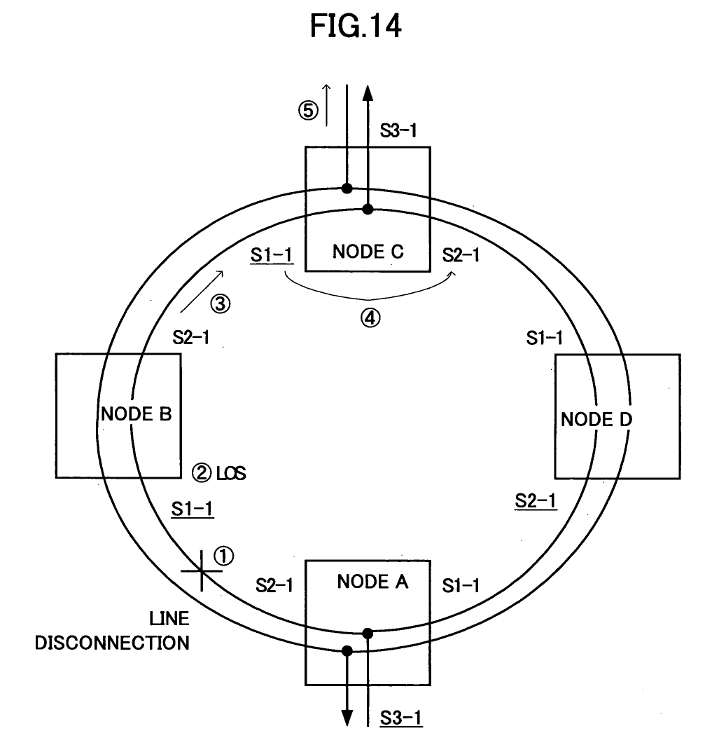

FIG. 14 is a drawing showing an exemplary configuration of a UPSR network using the communication apparatus of the fifth embodiment of the present invention as a node. In FIG. 14, the lines that are illustrated with underlined numerals indicate configuration set lines. Furthermore, numerals \mathring{1} to \mathring{5} in FIG. 14 correspond to step numbers described below.
(1) A fault occurs in a line between nodes A and B.
(2) A line alarm LOS is generated at S1-1 of the node B.
(3) The node B, detecting the line alarm in line S1-1, transmits line alarm information by using POH in the STS bundle of line S2-1.
(4) A node C switches its concatenation information reception line from line S1-1 serving as its configuration set line to line S2-1 in accordance with the POH of the line alarm information from the line S1-1 direction, and changes line format according to the line alarm information.
(5) The node C transmits the line alarm information by placing it on the POH in the STS bundle of line S3-1.

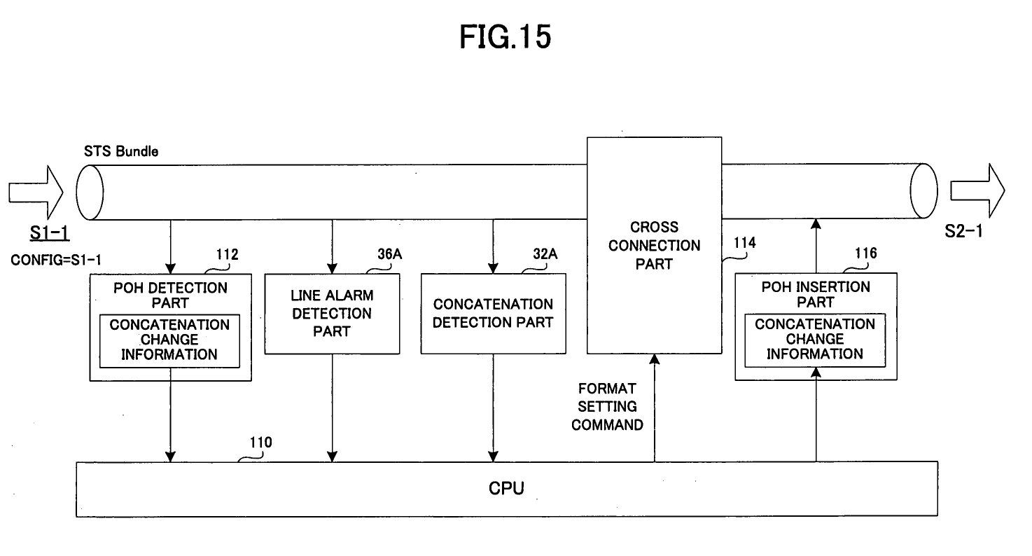

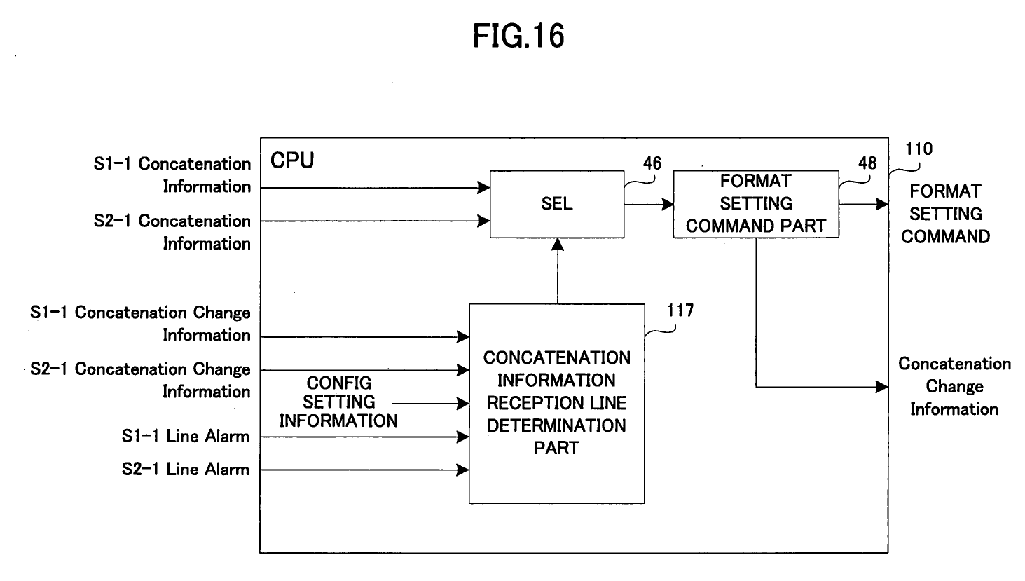

FIG. 15 is a drawing showing a configuration of a communication apparatus having an STS function according to a sixth embodiment of the present invention, and FIG. 16 is a drawing showing a configuration of a software process function in a CPU 110 shown in FIG. 15. In FIGS. 15 and 16, like components are denoted with like numerals as of FIGS. 12 and 13.

In FIG. 15, the concatenation detection part 32A detects concatenation information from H1, H2 bytes which are pointers in the SOH in the input signals in line S1-1, and reports the detection results to the CPU 110. The line alarm detection part 36A detects line alarms including LOS, LOF, and AIS-L of line S1-1 and reports the detection results to the CPU 110.

A POH detection part 112 extracts concatenation change information from, for example, G1 byte, of a POH of an input signal of the line S1-1, and reports the extracted information to the CPU 110. Here, the POH does not terminate but instead remains to be sent to the next node. A cross-connection part 114 executes line format setting when receiving a format setting execution command from the CPU 110.

A POH insertion part 116 inserts the concatenation change information into the G1 byte of the POH. A same configuration is also provided in the other direction from the line S2-1 to the line S1-1.

In FIG. 16, the concatenation information reception line determination part 117 determines the reception line of the concatenation information and switches the selector 46 in accordance with, for example, the concatenation change information, the line alarm, and/or the configuration setting information of both lines. Here, for the reception line of the concatenation information, priority is given to the line from which concatenation change information is received. However, in a case where concatenation change information is received from both lines, priority is given to the concatenation information of the configuration set line.

In a case where a line alarm is generated, the concatenation information reception line determination part 117 receives concatenation information from the line where the alarm is generated. In a case where the line alarm is generated in both lines or in a case where no alarm is generated either line, priority is given to the concatenation information of the configuration set line.

The format setting command part 48, in accordance with the concatenation information selected by the selector 46, reports the format setting command to the cross-connection part 114 and also reports the concatenation change information to the POH insertion part 116 of the path in the STS bundle where the format setting is changed.

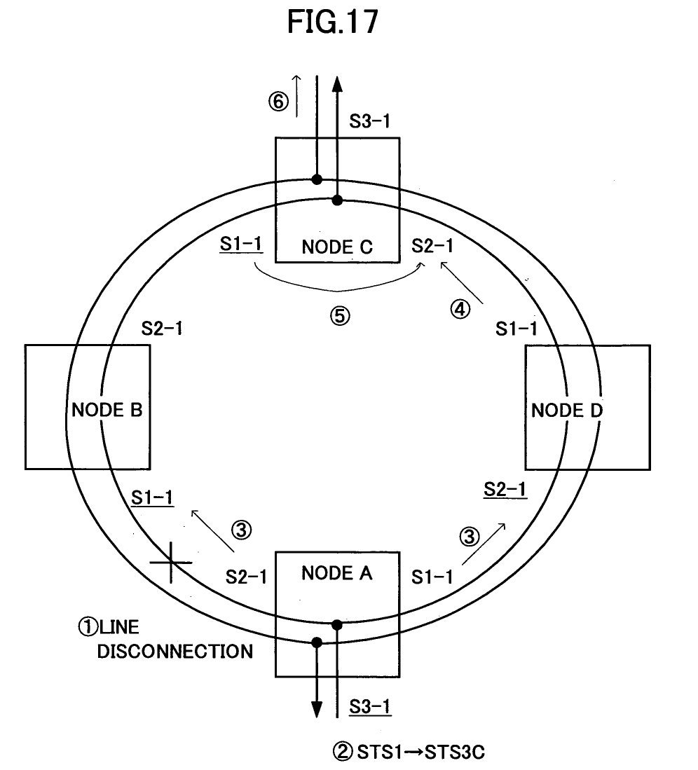

FIG. 17 is a drawing showing an exemplary configuration of a UPSR network using the communication apparatus of the sixth embodiment of the present invention as a node. In FIG. 17, the lines that are illustrated with underlined numerals indicate configuration set lines. Furthermore, numerals \mathring{1} to \mathring{6} in FIG. 17 correspond to step numbers described below.
(1) A fault occurs in a line between nodes A and B.
(2) An input signal format of line S3-1 of node A changes from STS-1 to STS-3C.
(3) The node A changes line format of its own node, and transmits concatenation information indicating change of concatenation information in the STS bundle with use of the POH in the STS bundle of lines S1-1 and S2-1.
(4) Since the configuration setting of node D is originally line S2-1, the node D uses the S2-1 concatenation information as is for changing line format, overwrites the concatenation information of the POH, and transmits the information to line S1-1.
(5) Node C switches the reception line of the concatenation information to line S2-1 for receiving concatenation change information from line S2-1, and changes format based on the concatenation information.
(6) Since the node B line format is unable to change format since the line disconnection at the reception side prevents the concatenation change information from reaching the node B, the node C the line remains as STS-1, and line format cannot be changed with the concatenation information from line S1-1 which is the configuration set line of node B. However, the node C is able to switch the concatenation information reception line to line S2-1 since the concatenation information is received from line S2-1, thereby allowing the line format to be changed to STS-3C based on the concatenation change information. Further, the node C overwrites the concatenation information of the POH and transmits the information to the line S3-1.

Thus, the node that changes the line format transmits the concatenation change information using the POH, and line format change can be executed by priority use of the concatenation information of the line from which concatenation change information is received. Accordingly, quick recovery can be achieved in a case where a fault occurs during switching of line format in the UPSR network.

Hence, automatic setting of format can be precisely achieved in a case where a fault occurs in the UPSR network by selecting the reception line of the concatenation information according to the comparison of the line alarm information of each line, the LOP-P of all paths in the STS bundle, and the AIS-P state of all paths, thereby enabling recovery in a case where a fault occurs when using the STS bundle line in the UPSR network.

Furthermore, by transmitting remote line alarm information or concatenation change information with use of the POH in the STS bundle information and selecting the reception line of the concatenation information according to the transmitted information, automatic setting of format can be precisely achieved in a case where a fault occurs in the UPSR network, and recovery of the fault in using the STS bundle line in the UPSR network can be achieved.

Furthermore, by providing a circuit configuration for enabling hardware to execute determination and switching of the reception line of the concatenation information, the automatic setting time of the entire network can be reduced, and quick recovery can be achieved in a case where a fault occurs during switching of line format in the UPSR network.

The above-described embodiment of the present invention, therefore, provides an STS bundle line enabling precise and quick recovery when a fault occurs during line format changing in the UPSR network, and provides an STS bundle line applicable apparatus having a highly reliable fault recovery function.

Additionally, one cross-connection corresponds to one configuration setting with respect to through-stations such as nodes B and D in FIG. 14. Furthermore, since two cross-connections (one between lines S1-1 and S3-1 and another between lines S2-1 and S3-1) correspond to one configuration setting with respect to add/drop stations such as nodes A and C in FIG. 14, the configuration settings for lines S1-1, S2-1, and S3-1 are executed simultaneously with the same setting.

Since the configuration shown in FIG. 4 and/or FIG. 6 executes configuration switching by comparing alarm information of lines S1-1 and S2-1 at through-stations such as nodes B and D, such nodes are applicable when considering that the cross-connection is set between the lines S1-1 and S2-1. Furthermore, in the configuration shown in FIG. 12 and/or FIG. 15, through-stations may be provided with bidirectional lines S1-1 and S2-1, to thereby execute configuration switching by comparing alarm information of both directions.

It is to be noted that the present invention is not limited to application to SONET, but may alternatively be applied to SDH (Synchronous Digital Hierarchy).

It is to be noted that: the line alarm detection parts 36A and 36B correspond to a line alarm detection part; the AIS-P detection parts 38A and 38B correspond to a path alarm detection part; the concatenation detection parts 32A and 32B correspond to a concatenation information detection part; the concatenation information reception line determination parts 44, 56, 108 and 117, the selector 46, the configuration in FIG. 8, and the configuration in FIG. 9 correspond to a concatenation information reception line selection part; the LOP-P detection parts 51A and 51B correspond to a pointer loss detection part; the alarm state monitor timer 57 and the timer part 65 correspond to a timer part; the ACME 90 and the ACMW 92 correspond to a storage part; the POH insertion part 106 corresponds to a remote alarm information insertion part; the POH detection part 102 corresponds to a remote alarm information detection part; the POH insertion part 116 corresponds to a concatenation change information insertion part; and the POH detection part 112 corresponds to a concatenation change information detection part.

Further, the present invention is not limited to these embodiments, but various variations and modifications may be made without departing from the scope of the present invention.

1. A line format setting method comprising the steps of:
detecting a line alarm of each line in a plurality of lines;
inserting path alarm information into all paths inside a line from which the line alarm is detected;
detecting the path alarm information in all paths inside the plurality of lines;
detecting concatenation information of each of the plurality of lines;
selecting a reception line for receiving the concatenation information in accordance with the path alarm information in all paths inside the plurality of lines; and
setting a line format of an STS bundle line by using the concatenation information of the selected reception line.

2. A line format setting method comprising the steps of:
detecting a line alarm of each line in a plurality of lines;
inserting path alarm information into all paths inside a line from which the line alarm is detected;
detecting the path alarm information in all paths inside the plurality of lines;
detecting pointer loss information of each path in the plurality of lines;
detecting concatenation information of each of the plurality of lines;
selecting a reception line for receiving the concatenation information in accordance with the path alarm information in all paths inside the plurality of lines and the pointer loss information of each path in the plurality of lines; and
setting a line format of an STS bundle line by using the concatenation information of the selected reception line.

3. A line format setting method comprising the steps of:
detecting a line alarm of each line in a plurality of lines;
inserting path alarm information into all paths inside a line from which the line alarm is detected;
inserting remote alarm information in overhead information when the line alarm is detected;
sending the remote alarm information to another line;
detecting the remote alarm information of each of the plurality of lines;
detecting concatenation information of each of the plurality of lines;
selecting a reception line for receiving the concatenation information in accordance with the path alarm information in all paths inside the plurality of lines and the remote alarm information of each of the plurality of lines; and
setting a line format of an STS bundle line by using the concatenation information of the selected reception line.

4. A line format setting method comprising the steps of:
detecting a line alarm of each line in a plurality of lines;
inserting path alarm information into all paths inside a line from which the line alarm is detected;
detecting concatenation change information of each of the plurality of lines;
detecting concatenation information of each of the plurality of lines;
selecting a reception line for receiving the concatenation information in accordance with the path alarm information in all paths inside the plurality of lines and the concatenation change information of each of the plurality of lines; and
inserting remote alarm information in overhead information and sending the remote alarm information to another line when setting a line format of an STS bundle line by using the concatenation information of the selected reception line.

5. A communication apparatus for setting a line format of an STS bundle line, the communication apparatus comprising:
a line alarm detection part for detecting a line alarm of each line in a plurality of lines and inserting path alarm information into all paths inside a line from which the line alarm is detected;
a path alarm detection part for detecting path alarm information in all paths inside the plurality of lines;
a concatenation information detection part for detecting concatenation information of each of the plurality of lines; and
a concatenation information reception line selection part for selecting a reception line for receiving the concatenation information in accordance with the path alarm information in all paths inside the plurality of lines;
wherein the line format of the STS bundle line is set by using the concatenation information of the selected reception line.

6. A communication apparatus for setting a line format of an STS bundle line, the communication apparatus comprising:
a line alarm detection part for detecting a line alarm of each line in a plurality of lines and inserting path alarm information into all paths inside a line from which the line alarm is detected;
a path alarm detection part for detecting path alarm information in all paths inside the plurality of lines;
a pointer loss detection part for detecting pointer loss information of each path in the plurality of lines;
a concatenation information detection part for detecting concatenation information of each of the plurality of lines;
a concatenation information reception line selection part for selecting a reception line for receiving the concatenation information in accordance with the path alarm information in all paths inside the plurality of lines and the pointer loss information of each path in the plurality of lines;
wherein the line format of the STS bundle line is set by using the concatenation information of the selected reception line.

7. The communication apparatus as claimed in claim 6, further comprising:
a timer part for measuring a pointer loss period of each of path in the plurality of lines and enabling the concatenation information reception line selection part to select the reception line for receiving concatenation information when the pointer loss period exceeds a predetermined value.

8. The communication apparatus as claimed in claim 6, further comprising:
slots corresponding to the plurality of lines, wherein the slots that are used for a Unidirectional Path Switched Ring are fixed.

9. The communication apparatus as claimed in claim 6, further comprising:
slots corresponding to the plurality of lines; and
a memory part for storing ring opponent line information of each of the plurality of lines;
wherein the slots that are used for a Unidirectional Path Switched Ring are not specified,
wherein the concatenation information reception line selection part selects the reception line for receiving concatenation information in accordance with the path alarm information in all paths inside the plurality of lines and the pointer loss information of each path in the plurality of lines that are selected according to the ring opponent line information.

10. The communication apparatus as claimed in claim 9, wherein the ring opponent line information is generated by using memory information used for setting a cross-connection.

11. A communication apparatus for setting a line format of an STS bundle line, the communication apparatus comprising:
a line alarm detection part for detecting a line alarm of each line in a plurality of lines and inserting path alarm information into all paths inside a line from which the line alarm is detected;
a remote alarm information insertion part for inserting remote alarm information in overhead information when the line alarm is detected and sending the remote alarm information to another line;
a remote alarm information detection part for detecting the remote alarm information of each of the plurality of lines;
a concatenation information detection part for detecting concatenation information of each of the plurality of lines;
a concatenation information reception line selection part for selecting a reception line for receiving the concatenation information in accordance with the path alarm information in all paths inside the plurality of lines and the remote alarm information of each of the plurality of lines;
wherein the line format of the STS bundle line is set by using the concatenation information of the selected reception line.

12. A communication apparatus for setting a line format of an STS bundle line, the communication apparatus comprising:
a line alarm detection part for detecting a line alarm of each line in a plurality of lines and inserting path alarm information into all paths inside a line from which the line alarm is detected;
a concatenation change information detection part for detecting concatenation change information of each of the plurality of lines;
a concatenation information detection part for detecting concatenation information of each of the plurality of lines;
a concatenation information reception line selection part for selecting a reception line for receiving the concatenation information in accordance with the path alarm information in all paths inside the plurality of lines and the concatenation change information of each of the plurality of lines; and
a concatenation change information insertion part for inserting remote alarm information in overhead information and sending the remote alarm information to another line when setting a line format of an STS bundle line by using the concatenation information of the selected reception line.
